(19) United States
(12) Patent Application Publication
(10) Pub. No.: US 2012/0211270 A1
(43) Pub. Date: Aug. 23, 2012

(54) METHOD OF MANUFACTURING PRINTED WIRING BOARD AND PRINTED WIRING BOARD

(75) Inventor: Hideaki YOSHIMURA, Suzaka (JP)

(73) Assignee: FUJITSU LIMITED, Kawasaki-shi (JP)

(21) Appl. No.: 13/399,107

(22) Filed: Feb. 17, 2012

(30) Foreign Application Priority Data
Feb. 21, 2011 (JP) 2011-035113

(51) Int. Cl. H05K 1/11; H05K 3/46; H05K 3/42

(52) U.S. Cl. 174/261; 29/852

(57) ABSTRACT

A method of manufacturing a printed wiring board includes forming a first hole penetrating a base having conductivity, closing an opening of the first hole with a film, filling an insulating material into the first hole after closing the opening, removing the film after filling the insulating material, forming a plurality of second holes penetrating the insulating material, and forming a film having conductivity on an inner surface of each of the second holes to form a plurality of wirings penetrating the insulating material.

### CROSS-REFERENCE TO RELATED APPLICATIONS

This application is based upon and claims the benefit of priority of the prior Japanese Patent Application No.2011-35113, filed on Feb. 21, 2011, the entire contents of which are incorporated herein by reference.

### FIELD

The embodiments discussed herein are related to a method of manufacturing a printed wiring board and a printed wiring board.

### BACKGROUND

In recent years, a printed wiring board having a low coefficient of thermal expansion which is close to a silicon wafer having a coefficient of thermal expansion of about 3 to 3.5 ppm/° C., is required. For example, by appropriately selecting a fiber material used for a prepreg material of a base and a material used for the base, it is attempted to reduce thermal expansion of the base of the printed wiring board. However, such a base of a printed wiring board generally has a coefficient of thermal expansion of 11 ppm/° C. or more, and thus it is difficult to obtain a coefficient of thermal expansion close to that of a silicon wafer.

Thus, as an improvement method, it is known that instead of glass fiber, a prepreg material in which a synthetic resin is impregnated into inorganic fiber such as carbon fiber having a high elastic modulus more than about 100 GPa and a low coefficient of thermal expansion equal to or less than 1 ppm/° C. is used for a base. In addition, it is also known that instead of inorganic fiber, an alloy plate having a low thermal expansion property such as invar material is used for a core of a printed wiring board. It should be noted that inorganic fiber and an alloy plate such as invar material are conductive materials.

Here, a printed wiring board for which such an improvement method is used will be described. FIG. 20 is a cross-sectional view of an example of a printed wiring board. In the printed wiring board 100 illustrated in FIG. 20, a conductive material having a low coefficient of thermal expansion, such as inorganic fiber, e.g., carbon fiber, or invar material, is used for a base 101. In the printed wiring board 100, wiring layers 103 are formed by etching copper foils adhered on a front surface 101A and a back surface 1016 of the base 101 with an insulating layer 102. Since the base 101 is the conductive material, the printed wiring board 100 has to have a structure to electrically insulate through holes 104, which connect between the wiring layer 103 on the front surface 101A and the wiring layer 103 on the back surface 1016, from the base 101. Therefore, in the printed wiring board 100, prior to forming the wiring layers 103, large pre-holes 105 are formed in portions where the through holes 104 are to be formed, and are filled with an insulating material 106 such as epoxy. As a result, a double structure to electrically insulate the base 101 and the through holes 104 from each other with the insulating material 106 is provided.

Therefore, in the printed wiring board 100 in which the base 101 of the conductive material is used, the insulating material 106 insulates the through holes 104 and the base 101 from each other. However, in the printed wiring board 100, one pre-hole 105 is required to form one through hole 104. Thus, when the number of the through holes 104 is increased, the number of the pre-holes 105 increases, and hence it is required to ensure a space for the pre-holes 105. It is also known that in order to reduce the number of the pre-holes 105 as compared to the number of the through holes 104, a plurality of through holes 104 is formed in one pre-hole 105.

Japanese Laid-open Patent Application Publication Nos. 2001-15654, 2002-353588, 2009-170500, and 2004-119691 are examples of related art.

However, the surface area of the inside of the pre-hole 105 formed through the front surface 101A and the back surface 1016 of the base 101 depends on the magnitude of the inner diameter of each through hole 104, and increases in accordance with the number of the through holes 104 arranged in the pre-hole 105. Therefore, in a step of filling the melted insulating material 106 into the pre-hole 105, when the inner diameter of the pre-hole 105 is increased, an amount of the insulating material 106 filled into the pre-hole 105 also increases. As a result, when the amount of the insulating material 106 increases, the insulating material 106 hangs down from the bottom of the pre-hole 105 owing to its weight. Thus, the workload is great in filling the insulating material 106 into the pre-hole 105. In addition, when the wiring layer 103 is multilayered, the thickness of the base 101 having a low coefficient of thermal expansion is increased in order to suppress increase in coefficient of thermal expansion caused by the wiring layer 103. Then, as the thickness of the base 101 increases, the wall area of the inner circumference of the pre-hole 105 also increases. Thus, the amount of the insulating material 106 filled into the pre-hole 105 also increases. As a result, the insulating material 106 hangs down from the bottom of the pre-hole 105 owing to its weight.

Therefore, in order to prevent the insulating material 106 filled in the pre-hole 105 from hanging down, increasing the viscosity of the insulating material 106 is considered, but there are limitations on increasing the viscosity. Further, when the viscosity of the insulating material 106 is excessively increased, it is difficult to fill the insulating material 106 into the pre-hole 105, and the workload of filling increases.

### SUMMARY

According to an aspect of the invention, a method of manufacturing a printed wiring board includes forming a first hole penetrating a base having conductivity, closing an opening of the first hole with a film, filling an insulating material into the first hole after closing the opening, removing the film after filling the insulating material, forming a plurality of second holes penetrating the insulating material, and forming a film having conductivity on an inner surface of each of the second holes to form a plurality of wirings penetrating the insulating material.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a cross-sectional view illustrating an example of a printed wiring board of Embodiment 1.

FIGS. 2A to 2G are diagrams illustrating an example of a method for manufacturing the printed wiring board of Embodiment 1.

FIGS. 3A to 3E are diagrams illustrating the example of the method for manufacturing the printed wiring board of Embodiment 1.

FIG. 4 is a diagram illustrating an example of through holes formed in a pre-hole of the printed wiring board of Embodiment 1.

FIG. 5 is a cross-sectional view illustrating an example of the printed wiring board (a multilayer printed wiring board) of Embodiment 1.

FIG. 6 is a cross-sectional view illustrating an example of the printed wiring board (a buildup printed wiring board) of the Embodiment 1.

FIG. 7 is a cross-sectional view illustrating an example of a printed wiring board of Embodiment 2.

FIGS. 8A to 8G are diagrams illustrating an example of a method for manufacturing the printed wiring board of the Embodiment 2.

FIGS. 9A to 9D are diagrams illustrating the example of the method for manufacturing the printed wiring board of Embodiment 2.

FIGS. 10A to 10E are diagrams illustrating an example of a method for manufacturing a printed wiring board of Embodiment 3.

FIGS. 11A to 11C are diagrams illustrating the example of the method for manufacturing the printed wiring board of Embodiment 3.

FIGS. 12A to 12E are diagrams illustrating an example of a method for manufacturing a printed wiring board of Embodiment 4.

FIGS. 13A to 13D are diagrams illustrating the example of the method for manufacturing the printed wiring board of Embodiment 4.

FIG. 14 is a cross-sectional view illustrating an example of a printed wiring board of Embodiment 5.

FIGS. 15A to 15G are diagrams illustrating an example of a method for manufacturing the printed wiring board of Embodiment 5.

FIGS. 16A to 16D are diagrams illustrating the example of the method for manufacturing the printed wiring board of Embodiment 5.

FIG. 17 is a diagram illustrating an example of through holes formed in a pre-hole of an embodiment.

FIG. 18 is a diagram illustrating an example of through holes formed in a pre-hole of an embodiment.

FIG. 19 is a diagram illustrating an example of through holes formed in a pre-hole of an embodiment.

FIG. 20 is a cross-sectional view illustrating an example of a printed wiring board.

### DESCRIPTION OF EMBODIMENTS

Hereinafter, embodiments of a method for manufacturing a printed wiring board and a printed wiring board which are disclosed in this application will be described in detail on the basis of the drawings. It should be noted that the disclosed technology is not limited by the embodiments.

### Embodiment 1

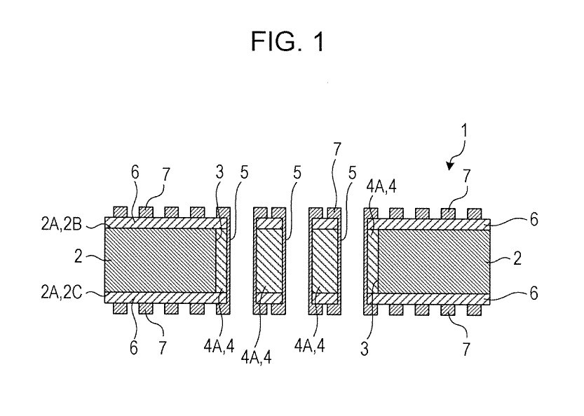

FIG. 1 is a cross-sectional view illustrating an example of a printed wiring board of Embodiment 1. The printed wiring board 1 illustrated in FIG. 1 is, for example, a double-sided wiring board in which wiring layers are formed on both surfaces thereof. The printed wiring board 1 includes a base 2 of a conductive material and a pre-hole 3 formed through surface portions 2A of the base 2. In addition, the printed wiring board 1 includes a hole-plugging portion 4A obtained by filling an insulating material 4 into the pre-hole 3 to plug the pre-hole 3, and a plurality of through holes 5 formed in the hole-plugging portion 4A within the pre-hole 3. Moreover, the printed wiring board 1 includes insulating layers 6 formed on the surface portions 2A of the base 2 and wiring layers 7 formed by etching copper foils laminated on the insulating layers 6.

The base 2 is, for example, a conductive base having a low coefficient of thermal expansion, such as carbon fiber reinforce plastic (CFRP) which is formed by hot-pressing a plurality of prepreg materials such as woven fabrics or nonwoven fabrics of carbon fiber. It should be noted that a low coefficient of thermal expansion is, for example, a coefficient of thermal expansion of about 5 ppm/° C. or less. The base 2 has, as a core, for example, an unclad material in which an insulating resin is impregnated into a base such as glass cloth and a copper foil is attached and laminated thereto to obtain a CCL (Copper Clad Laminate) and the copper foil of the CCL is removed by etching. In addition, other than inorganic fiber such as carbon fiber, the base 2 may be a composite of aluminum+carbon, a composite of copper+carbon, an alloy of copper+silver, an invar material of iron+nickel, or the like. Moreover, the base 2 may be a super invar material of iron+nickel+cobalt, a stainless invar material of iron+cobalt+chromium, a Fe—Pt alloy of iron+platinum, a Fe—Pb alloy of iron+lead, or the like.

For the insulating material 4, for example, an epoxy thermosetting resin is used. It should be noted that the insulating material 4 is a resin having a low coefficient of thermal expansion, in which a silica filler is mixed in order to decrease the coefficient of thermal expansion of the insulating material 4. In addition, for the insulating material 4, for example, a thermoplastic resin or an ultraviolet curable resin, or the like may be used. The hole-plugging portion 4A plugs the pre-hole 3 by thermally curing the insulating material 4 filled in the pre-hole 3. In the hole-plugging portion 4A within the pre-hole 3, the plurality of through holes 5 are formed so as to conduct the wiring layers 7, which are located on both a front surface 2B and a back surface 2C that are the surface portions 2A of the base 2, to each other.

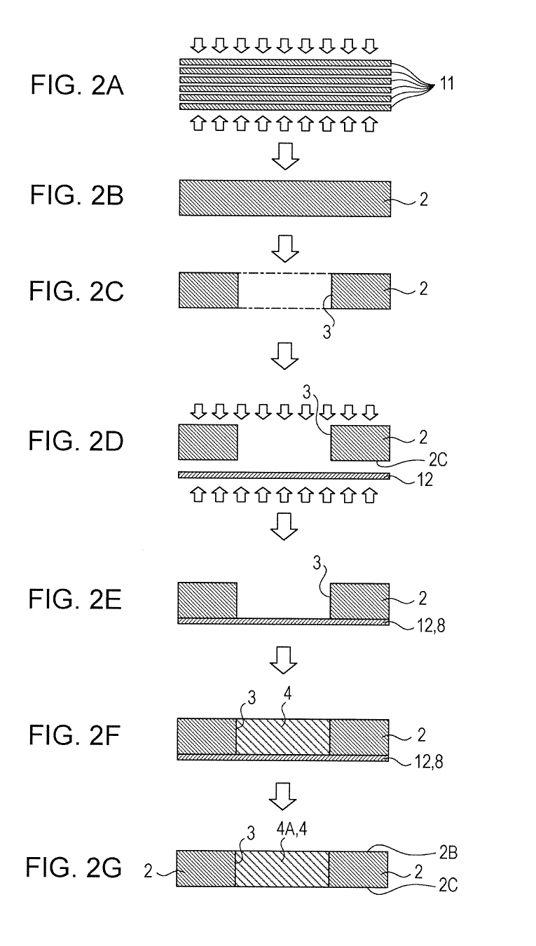

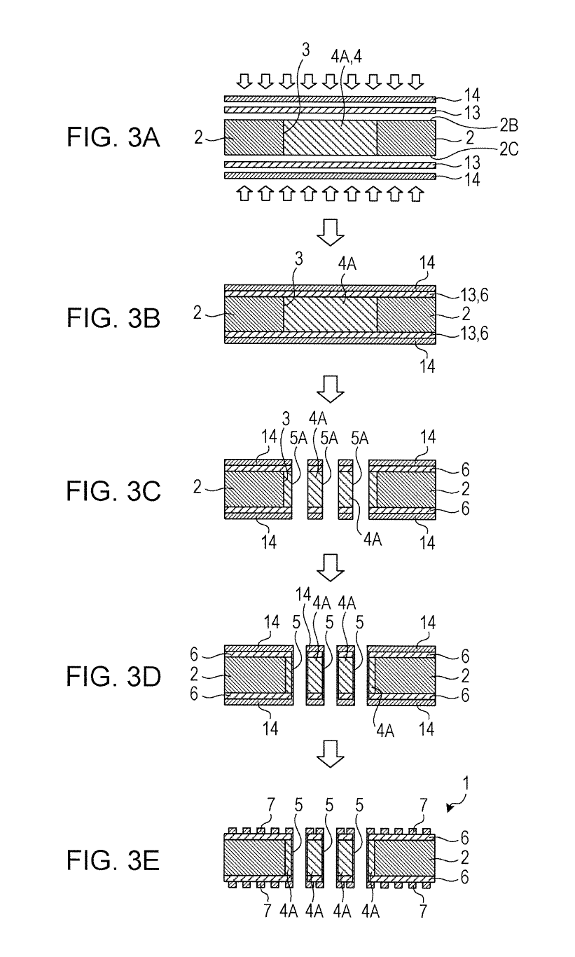

Next, a method for manufacturing the printed wiring board 1 of Embodiment 1 will be described. FIGS. 2A to 2G and FIGS. 3A to 3E are diagrams illustrating an example of the method for manufacturing the printed wiring board 1 of Embodiment 1. In the manufacturing method of FIG. 2A, a base forming step of forming the base 2 is executed by using a hot press machine (not illustrated). The hot press machine stacks a plurality of prepreg materials 11 in which a synthetic resin is impregnated into a woven fabric or nonwoven fabric of carbon fiber to come into B stage. It should be noted that for the carbon fiber, for example, fiber having a coefficient of thermal expansion of about 0 ppm/° C. and an elastic modulus of about 370 GPa is used. In addition, even when a resin used for FR4 and the like is applied to the carbon fiber, properties of a coefficient of thermal expansion of about 0 ppm/° C. and an elastic modulus of about 80 GPa are obtained as property values of a low thermal expansion base (CFRP) after curing. Then, the hot press machine hot-presses these stacked prepreg materials 11 to form the base 2 having a low coefficient of thermal expansion as illustrated in FIG. 2B. Next, in the manufacturing method of FIG. 2C, a pre-hole forming step is executed by using a boring machine (not illustrated). The boring machine forms, in the surface portions 2A of the base 2, the pre-hole 3 having a predetermined size and extending through the front and back thereof.

In the manufacturing method of FIG. 2D, a bottom forming step of forming a bottom 8 of the pre-hole 3 is executed by using a hot press machine (not illustrated). The hot press machine stacks a separation film 12 having an adhesive layer, on the back surface 2C of the base 2 to attach the separation film 12 to the back surface 2C of the base 2 with the adhesive layer. It should be noted that the adhesive layer is an acrylic adhesive layer having heat resistance and releasability, such as a polyimide tape. The separation film 12 is a film such as a PET (polyethylene terephthalate) film. As a result, as illustrated in FIG. 2E, the separation film 12 constitutes the bottom 8 which closes the opening of the pre-hole 3 on the bottom side.

Further, in the manufacturing method of FIG. 2F, a filling step of filling the melted insulating material 4 for plugging, into the pre-hole 3 of the base 2 is executed by using a filling machine (not illustrated) such as a vacuum printing machine. It should be noted that for the insulating material 4, for example, a resin having a coefficient of thermal expansion of about 33 ppm/° C. and an elastic modulus of about 4.7 GPa, in which a silica filler is mixed in order to decrease its coefficient of thermal expansion, is used. In this case, the separation film 12 constitutes the bottom 8 within the pre-hole 3, and thus can prevent the filled insulating material 4 from hanging down to the bottom side. The vacuum printing machine prints the insulating material 4 at the position of the pre-hole 3 by using a metal mask in a vacuum state, and then exposes the insulating material 4 to the atmosphere, whereby the insulating material 4 is filled into the pre-hole 3 from the front surface 2B side of the base 2 without occurrence of voids in the pre-hole 3.

In the manufacturing method of FIG. 2G, the insulating material 4 filled in the pre-hole 3 is thermally cured by using a heater (not illustrated) to form the hole-plugging portion 4A. It should be noted that the insulating material 4 is cured, for example, at about 150° C. Therefore, the heater heats the insulating material 4 filled in the pre-hole 3, at about 150° C. for a predetermined time to form the hole-plugging portion 4A within the pre-hole 3. Then, the separation film 12 attached to the back surface 2C of the base 2 is separated therefrom. It should be noted that when, immediately after the insulating material 4 filled in the pre-hole 3 is thermally cured, the separation film 12 attached to the back surface 2C of the base 2 is separated without decreasing the heating temperature, the adhesive layer of the separation film 12 can be separated from the back surface 2C of the base 2 without remaining thereon. In addition, a grinding machine (not illustrated) grinds and planarizes the surface portions 2A of the base 2 and the surface of the hole-plugging portion 4A projecting on the base 2, for example, with a buff roll. As a result, subsequent steps such as a copper foil laminating step and a pattern forming step can smoothly be performed.

Further, in the manufacturing method of FIG. 3A, the copper foil laminating step of laminating copper foils 14 on the surface portions 2A of the base 2 is executed by using a hot press machine (not illustrated). The hot press machine places adhering prepreg materials 13 on the surface portions 2A of the base 2, further places the copper foils 14 on the adhering prepreg materials 13, and performs hot press. By performing hot press, the hot press machine causes the adhering prepreg materials 13 to form the insulating layers 6 on the surface portions 2A of the base 2, and laminates the copper foils 14 on the insulating layers 6, as illustrated in FIG. 3B. It should be noted that the adhering prepreg materials 13 are material containing glass fiber into which a synthetic resin for preventing exposure of carbon fiber is impregnated.

Further, in the manufacturing method of FIG. 3C, a through hole forming step is executed by using a boring machine (not illustrated). The boring machine forms a plurality of through-hole holes 5A in the hole-plugging portion 4A of the insulating material 4 filled in the pre-hole 3 of the base 2, on the basis of a designed arrangement configuration of the through holes 5. As a result, insulation of each through-hole hole 5A from each other as well as insulation of each through-hole hole 5A from the base 2 are ensured by the hole-plugging portion 4A of the insulating material 4. In addition, in the manufacturing method of FIG. 3D, a copper plating is provided to the inner circumferential wall surface of each through-hole hole 5A by using a plating apparatus (not illustrated). The plating apparatus provides, for example, a copper plating having a coefficient of thermal expansion of about 17 ppm/° C. to the inner circumferential wall surface of each through-hole hole 5A to form the through holes 5. Then, in the manufacturing method of FIG. 3E, a pattern forming step of forming the wiring layers 7 on the insulating layers 6 on the surface portions 2A of the base 2 is executed by using a patterning apparatus (not illustrated). The patterning apparatus forms resists on the copper foils 14 laminated on the insulating layers 6. In addition, the patterning apparatus etches the copper foils 14 on the insulating layers 6 to form the wiring layers 7 on the insulating layers 6. As a result, the printed wiring board 1 of Embodiment 1 is completed.

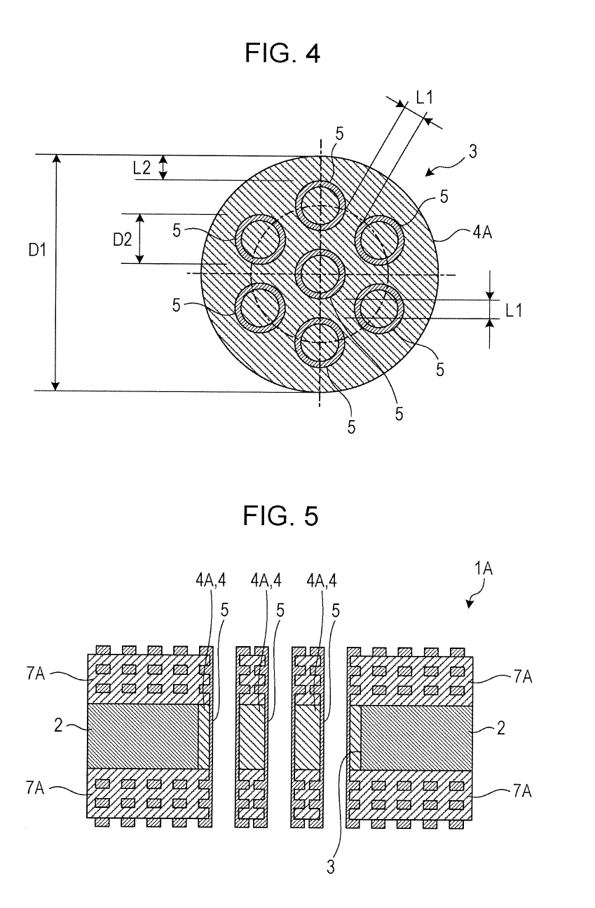

FIG. 4 is a diagram illustrating an example of the through holes 5 formed in the pre-hole 3 of the printed wiring board 1 of Embodiment 1. In the hole-plugging portion 4A within the pre-hole 3 illustrated in FIG. 4, seven through holes 5 are formed. In an existing arrangement configuration in which one pre-hole is formed for one through hole, for example, when the diameter of each through hole formed in a base of CFRP having a low coefficient of thermal expansion is 0.35 mm, it is necessary to form a pre-hole of 0.75 mm to 0.8 mm in consideration of accuracy of the position of each through hole. When the diameter D of a pre-hole is 0.75 mm, the area of the pre-hole required per through hole is D2×Π/4=0.752×Π/4≈0.589 (mm²). It should be noted that when the diameter of the pre-hole is 0.75 mm and the diameter of each through hole is 0.35 mm, an interval of 0.2 mm is required in order to ensure insulation between the base and each through hole and insulation between the through holes.

Thus, for example, it is assumed that the seven through holes 5 are formed at intervals of 0.2 mm or more (0.2 mm to 0.21 mm). In such a case, the diameter D1 of the pre-hole 3 illustrated in FIG. 4 is represented by the following equation where the diameter D2 of each through hole 5 is 0.35 mm, the interval L1 between the through holes 5 is 0.21 mm, and the interval L2 between the base 2 and each through hole 5 is 0.20 mm. D1=(D2×3)+(L1×2)+(L2×2) =(0.35×3)+(0.21×2)+(0.2×2). Then, the area of the pre-hole 3 is ((D2×3)+(L1×2)+(L2×2)) 2>Π/4=((0.35×3)+(0.21×2)+(0.2×2)) 2×Π/4=1.82×Π/4≈2.746 (mm²).

Thus, the area required per through hole 5 in the pre-hole 3 is 1/7 of the area of the pre-hole 3, namely, about 0.392 (mm²). Therefore, as compared to the arrangement configuration in which one pre-hole is formed for one through hole, the area of the pre-hole 3 required per through hole 5 in the pre-hole 3 is reduced by 33.4%. As a result, the arrangement density at which the through holes 5 are arranged in the pre-hole 3 is improved. In addition, in consideration of an arrangement configuration of the through holes which ensures insulation between the base 2 and the through holes 5 and insulation between the through holes 5, the through holes 5 are desirably arranged in the pre-hole 3 so as to have centers on a circle concentric with the pre-hole 3 as illustrated in FIG. 4.

In the manufacturing method of Embodiment 1, the separation film 12 is attached to the back surface 2C of the base 2 to constitute the bottom 8 which closes the opening of the pre-hole 3. Thus, when filling the insulating material 4, the bottom 8 can prevent the insulating material 4 filled in the pre-hole 3 from hanging down. As a result, the workload is reduced in the filling step of filling the insulating material 4 into the pre-hole 3, and hence the workload can be reduced when forming the plurality of through holes 5 in the pre-hole 3 of the conductive base 2.

In the printed wiring board 1 of Embodiment 1, the plurality of through holes 5 are formed in the single pre-hole 3, and thus the surface area of the pre-hole 3 required per through hole 5 in the pre-hole 3 can be suppressed. As a result, the surface area of the hole-plugging portion 4A in the pre-hole 3 decreases, and the amount of the insulating material 4 having a high coefficient of thermal expansion decreases. Thus, this can contribute to decrease in the coefficient of thermal expansion of the entire printed wiring board 1.

It should be noted that in Embodiment 1 described above, the double-sided printed wiring board 1 is exemplified as illustrated in FIG. 1. However, Embodiment 1 is also applicable to a multilayer printed wiring board. FIG. 5 is a cross-sectional view illustrating an example of a multilayer printed wiring board of Embodiment 1. It should be noted that the same components as those in the printed wiring board 1 illustrated in FIG. 1 are designated by the same reference characters, and thus the description of the overlapping configurations and operations is omitted. In the multilayer printed wiring board 1A illustrated in FIG. 5, double-sided copper-attached plates 7A in which circuits are formed are interposed on the wiring layers 7 laminated on the front and back of the double-sided printed wiring board 1, and are laminated with prepreg materials, thereby providing a multilayer structure. In other words, the present embodiment can also be applied to the multilayer printed wiring board 1A.

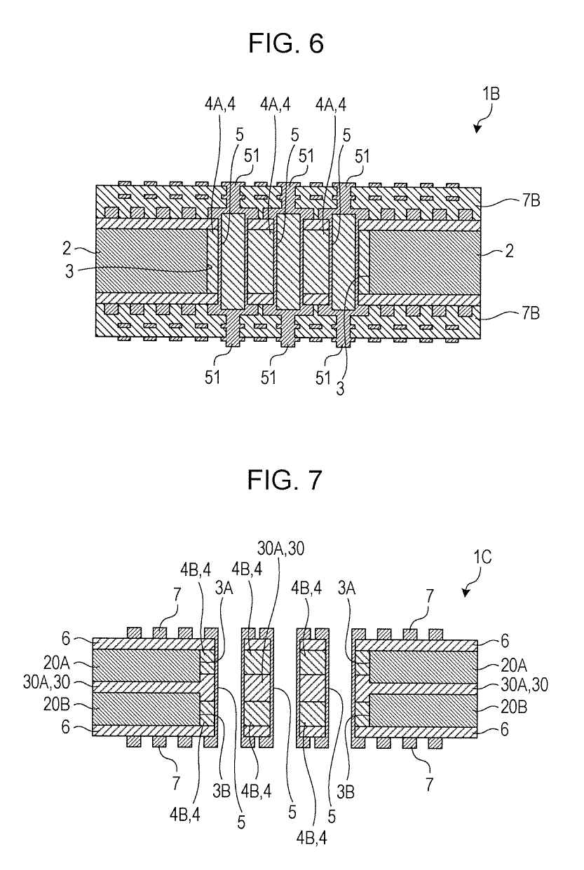

Further, FIG. 6 is a cross-sectional view illustrating an example of the printed wiring board (buildup printed wiring board) of Embodiment 1. It should be noted that the same components as those in the printed wiring board 1 illustrated in FIG. 1 are designated by the same reference characters, and the description of the overlapping configurations and operations is omitted. In the buildup printed wiring board 1B illustrated in FIG. 6, the insulating material 4 for plugging is filled into each through hole 5 formed in the double-sided printed wiring board 1, to form cover platings 51, and then buildup wiring layers 7B are laminated on the wiring layers 7. In other words, the present embodiment can also be applied to the buildup printed wiring board 1B.

It should be noted that in the method for manufacturing the printed wiring board 1 of Embodiment 1 described above, the separation film 12 is attached to the surface portion 2A of the base 2 on the bottom side to constitute the bottom 8 which closes the opening of the pre-hole 3 on the bottom side. Another embodiment will be described as Embodiment 2 below.

### Embodiment 2

FIG. 7 is a cross-sectional view illustrating an example of a printed wiring board of Embodiment 2. It should be noted that the same components as those in the printed wiring board 1 of Embodiment 1 are designated by the same reference characters, and thus the description of the overlapping configurations and operations is omitted. The printed wiring board 1C illustrated in FIG. 7 includes a first base 20A, a second base 20B, a first pre-hole 3A formed in a surface portion of the first base 20A, and a second pre-hole 3B formed in a surface portion of the second base 20B. In addition, the printed wiring board 1C includes an insulating layer 30A of an adhesive sheet 30 which adheres the surface portions of the first base 20A and the second base 20B to each other.

Further, the printed wiring board 1C includes a hole-plugging portion 4B formed by thermally curing the insulating material 4 filled in the first pre-hole 3A and the second pre-hole 3B, to plug the first pre-hole 3A and the second pre-hole 3B. In addition, the printed wiring board 1C includes a plurality of through holes 5 formed in the hole-plugging portion 4B so as to extend through the first pre-hole 3A, the insulating layer 30A, and the second pre-hole 3B. Moreover, the printed wiring board 1C includes insulating layers 6 formed on the surface portions of the first base 20A and the second base 20B, and wiring layers 7 formed by etching copper foils formed on the insulating layers 6.

The first base 20A is a conductive base having a low coefficient of thermal expansion, such as the aforementioned CFRP. Similarly, the second base 20B is also a conductive base having a low coefficient of thermal expansion, such as CFRP. The insulating layer 30A is formed of an insulating adhesive sheet 30 located between the surface portions of the first base 20A and the second base 20B. It should be noted that the adhesive sheet 30 corresponds to, for example, an epoxy material, and is a laminate of sheets brought into B stage. Alternatively, as the adhesive sheet 30, for example, a sheet in which an adhesive layer is formed on a polyimide film, or a thermoplastic material such as a liquid crystal polymer, may be used. The insulating layer 30A joins the surface portions of the first base 20A and the second base 20B to each other such that the first pre-hole 3A and the second pre-hole 3B overlap each other. The hole-plugging portion 4B is formed by thermally curing the insulating material 4 filled in the first pre-hole 3A and the second pre-hole 3B, and plugs the first pre-hole 3A and the second pre-hole 3B. In the hole-plugging portion 4B, the plurality of through holes 5 are formed so as to conduct the wiring layer 7 on the first base 20A to the wiring layer 7 on the second base 20B.

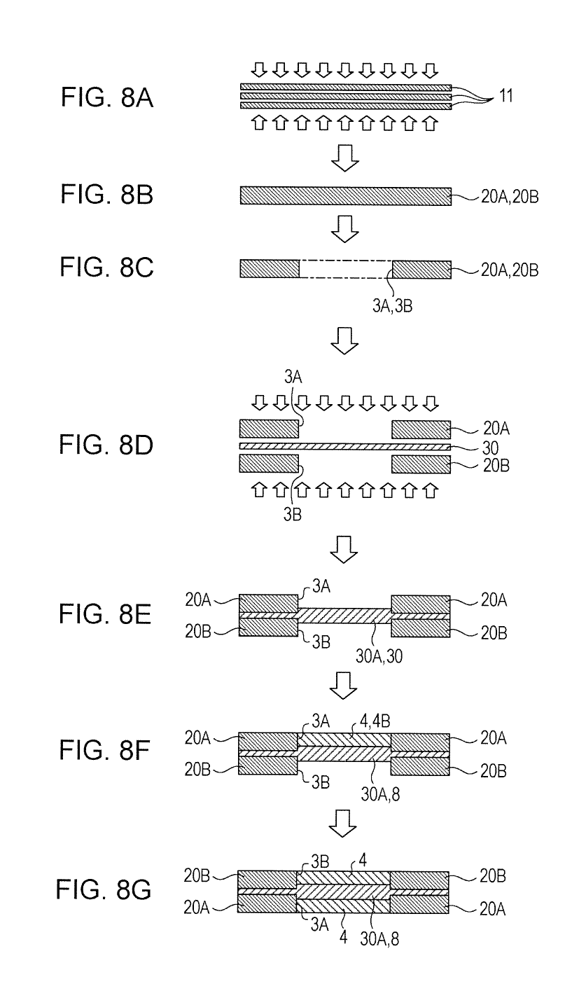

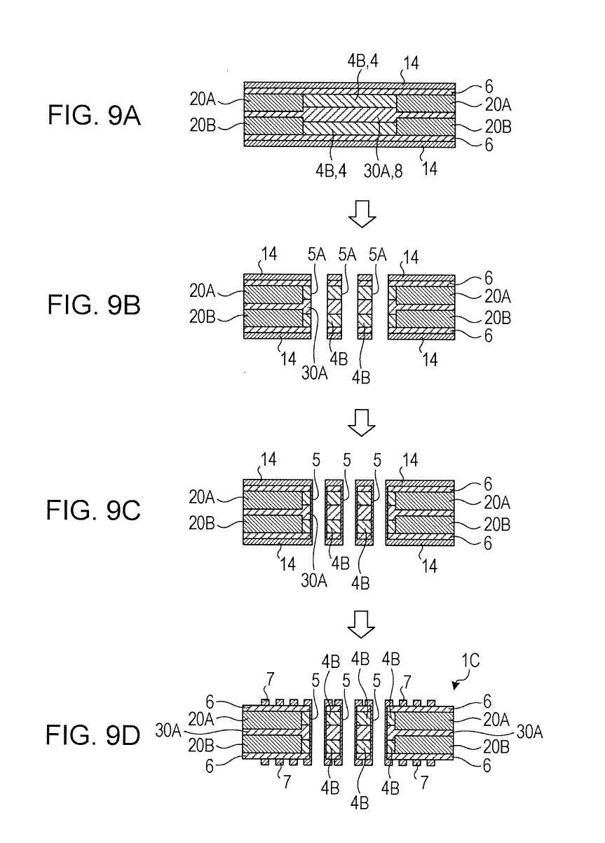

Next, a method for manufacturing the printed wiring board 1C of Embodiment 2 will be described. FIGS. 8A to 8G and FIGS. 9A to 9D are diagrams illustrating an example the method for manufacturing the printed wiring board 1C of Embodiment 2. In the manufacturing method of FIG. 8A, a base forming step of forming the first base 20A and the second base 20B is executed by using a hot press machine (not illustrated). The hot press machine stacks a plurality of prepreg materials 11 and hot-presses these stacked prepreg materials 11, to form the first base 20A and second base 20B having low coefficients of thermal expansion as illustrated in FIG. 8B. Next, in the manufacturing method of FIG. 8C, a pre-hole forming step is executed by using a boring machine (not illustrated). The boring machine forms, in the surface portion of the first base 20A, the first pre-hole 3A extending through the front and back thereof, and forms, in the surface portion of the second base 20B, the second pre-hole 3B extending through the front and back thereof.

In the manufacturing method of FIG. 8D, a joining step of joining the surface portions of the first base 20A and the second base 20B to each other is executed by using a hot press machine (not illustrated). The hot press machine locates the insulating adhesive sheet 30 between the surface portions of the first base 20A and the second base 20B such that the first pre-hole 3A and the second pre-hole 3B overlap each other. In addition, the hot press machine hot-presses the adhesive sheet 30 between the first base 20A and the second base 20B to form the insulating layer 30A which joins the surface portions of the first base 20A and the second base 20B to each other. As a result, the insulating layer 30A adheres the surface portion of the first base 20A and the surface portion of the second base 20B to each other and constitutes bottoms 8 which close the openings of the first pre-hole 3A and the second pre-hole 3B, as illustrated in FIG. 8E.

In the manufacturing method of FIG. 8F, a filling step is executed by using a filling machine (not illustrated). The filling machine, for example, causes the opening side of the first pre-hole 3A of the first base 20A to face upward, and fills the melted insulating material 4 into the first pre-hole 3A of the first base 20A. At that time, the insulating layer 30A constitutes the bottom 8 of the first pre-hole 3A, and thus can prevent the insulating material 4 filled in the first pre-hole 3A from hanging down to the opening side. In addition, a heater (not illustrated) thermally cures the insulating material 4 filled in the first pre-hole 3A. After the insulating material 4 filled in the first pre-hole 3A is thermally cured, the filling machine causes the opening side of the second pre-hole 3B to face upward. Further, the filling machine fills the melted insulating material 4 into the second pre-hole 3B of the second base 20B as illustrated in FIG. 8G. At that time, the insulating layer 30A constitutes the bottom 8 of the second pre-hole 3B, and thus can prevent the insulating material 4 filled in the second pre-hole 3B from hanging down to the opening side. Moreover, the heater thermally cures the insulating material 4 filled in the second pre-hole 3B. As a result, the heater causes the insulating material 4 thermally cured in the first pre-hole 3A and the second pre-hole 3B to form the hole-plugging portion 4B. In addition, a grinding machine (not illustrated) grinds and planarizes the surface portions of the first base 20A and the second base 20B and the surface of the hole-plugging portion 4B projecting on the surface portions. As a result, subsequent steps such as a copper foil laminating step and a pattern forming step can smoothly be performed.

It should be noted that in the manufacturing method of FIGS. 8F and 8G, the insulating material 4 filled in the first pre-hole 3A is thermally cured, and then the insulating material 4 filled in the second pre-hole 3B is thermally cured. However, the heater may not completely thermally cure the insulating material 4 filled in the first pre-hole 3A and may perform preliminary thermal curing in which the insulating material 4 filled in the first pre-hole 3A is thermally cured to such an extent that the insulating material 4 does not hang down to the opening side. In addition, after the insulating material 4 filled in the first pre-hole 3A is preliminarily thermally cured, the filling machine fills the insulating material 4 into the second pre-hole 3B. Then, the heater completely thermally cures the insulating material 4 in the first pre-hole 3A and the second pre-hole 3B. In this case, warpage of the printed wiring board 1C that can occur owing to different timings at which the insulating material 4 is thermally cured in the first pre-hole 3A and the second pre-hole 3B can be suppressed. In addition, when an ultraviolet curable insulating material is used as the insulating material 4, main baking in which the insulating material 4 is completely thermally cured may be executed after the insulating material 4 filled in the first pre-hole 3A and the second pre-hole 3B is preliminarily thermally cured.

In the manufacturing method of FIG. 9A, a copper foil laminating step of laminating copper foils 14 on the surface portions of the first base 20A and the second base 20B is executed by using a hot press machine (not illustrated). The hot press machine locates adhering prepreg materials 13 on the surface portions of the base 2, also locates the copper foils 14 on the adhering prepreg materials 13, and performs hot press. The hot press machine forms the insulating layers 6 on the surface portions of the first base 20A and the second base 20B and laminates the copper foils 14 on the insulating layers 6. Further, in the manufacturing method of FIG. 9B, a through hole forming step is executed by using a boring machine (not illustrated). The boring machine forms a plurality of through-hole holes 5A in the hole-plugging portion 4B of the insulating material 4 filled in the first pre-hole 3A and the second pre-hole 3B. As a result, insulation of each through-hole hole 5A from each other as well as insulation of each through-hole hole 5A from the first base 20A and the second base 20B are ensured by the hole-plugging portion 4B of the insulating material 4.

Further, in the manufacturing method of FIG. 9C, a copper plating is provided to the inner circumferential wall surface of each through-hole hole 5A by using a plating apparatus (not illustrated), to form the through holes 5. Then, in the manufacturing method of FIG. 9D, a pattern forming step of forming the wiring layers 7 on the insulating layers 6 on the surface portions of the first base 20A and the second base 20B is executed by using a patterning apparatus (not illustrated). As a result, the printed wiring board 1C of Embodiment 2 is completed.

In the manufacturing method of Embodiment 2, the insulating layer 30A which joins the surface portions of the first base 20A and the second base 20B to each other constitutes the bottoms 8 of the first pre-hole 3A and the second pre-hole 3B, and the bottoms 8 prevent the insulating material 4 filled in the first pre-hole 3A and the second pre-hole 3B from hanging down to the opening side. As a result, the workload is reduced in the filling step of filling the insulating material 4 into the first pre-hole 3A and the second pre-hole 3B, and hence the workload can be reduced when forming the plurality of through holes 5 in the first pre-hole 3A and second pre-hole 3B of the conductive first base 20A and second base 20B.

In the printed wiring board 1C of Embodiment 2, the first pre-hole 3A and the second pre-hole 3B constitute a single pre-hole 3, and the plurality of through holes 5 are formed in the pre-hole 3. Thus, the surface area of the pre-hole 3 required per through hole 5 in the pre-hole 3 can be suppressed. As a result, the surface area of the hole-plugging portion 4B in the pre-hole 3 decreases, and the amount of the insulating material 4 having a high coefficient of thermal expansion decreases. Thus, this can contribute to decrease in the coefficient of thermal expansion of the entire printed wiring board 1C.

The reason why the unclad material is used for the core of the insulating resin material in this embodiment is that the following advantageous effect is obtained even when the surface portions of the first base 20A and the second base 20B in which the pre-hole 3 is formed are simply laminated to each other through a prepreg material or the like. A problem that a resin whose viscosity is decreased flows in the pre-hole 3 owing to its surface tension and glass cloth of prepreg is exposed after lamination, to form voids, and a problem that a resin flows and drops from the pre-hole 3, can be solved.

In this embodiment, the low thermal expansion prepreg used actually in manufacture is a material in which a resin is impregnated into carbon fiber, and is a CFRP material having an elastic modulus of about 68 GPa and a coefficient of thermal expansion of 1 ppm/° C. as properties after thermal curing. A core material in which two materials (the first base 20A and the second base 20B) each having a plate thickness of 0.85 mm and obtained by laminating a plurality of (actually five) low thermal expansion prepregs are used and in which an unclad material of 100 μm and a material of about 60 μm as an adhesive layer are laminated, is used. Then, as a result of the arrangement configuration of the through holes 5 as illustrated in FIG. 4, the measured value of the coefficient of thermal expansion of the low thermal expansion core portion (not including the wiring layers 7 on the surface) is 4.75 ppm/° C. On the other hand, the measurement result of the coefficient of thermal expansion of the core portion produced by an existing method is 5.45 ppm/° C. Thus, the coefficient of thermal expansion is improved by about 13%. This is the case where the base of 0.85 mm is used. It is thought that when the ratio of the thickness of the low thermal expansion material to the thickness of the insulating layer which laminates the low thermal expansion base increases, the advantageous effect increases further.

It should be noted that in the manufacturing method of Embodiment 1 described above, the bottom 8 of the pre-hole 3 is formed of the separation film 12 attached to the back surface 2C of the base 2, but may be formed of the insulating layer 30A which laminates the copper foil 14 on the back surface 2C of the base 2. An embodiment of such a case will be described as Embodiment 3 below.

### Embodiment 3

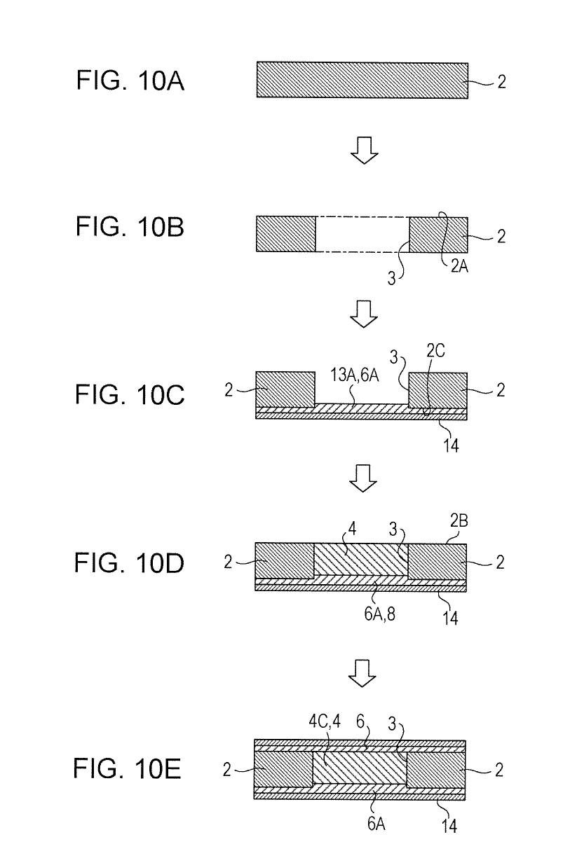

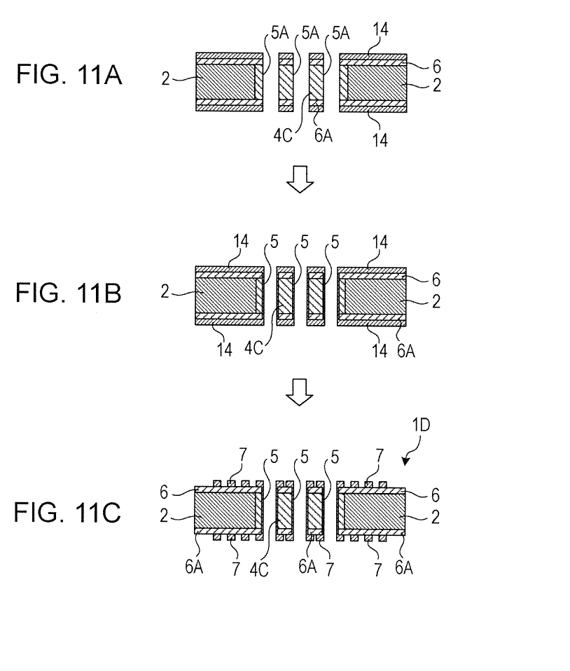

FIGS. 10A to 10E and FIGS. 11A to 11C are diagrams illustrating an example of a method for manufacturing of a printed wiring board 1D of Embodiment 3. It should be noted that the same components as those in the printed wiring board 1 of Embodiment 1 are designated by the same reference characters, and thus the description of the overlapping configurations and operations is omitted.

In the manufacturing method of FIG. 10A, a base forming step of forming a base 2 is executed by using a hot press machine (not illustrated). The hot press machine stacks a plurality of prepreg materials 11 having low coefficients of thermal expansion, and hot-presses these stacked prepreg materials 11, to form the base 2 having a low coefficient of thermal expansion. Next, in the manufacturing method of FIG. 10B, a pre-hole forming step of forming, in the surface portions 2A of the base 2, a pre-hole 3 extending through the front and back thereof.

In the manufacturing method of FIG. 10C, a bottom forming step is executed by using a hot press machine (not illustrated). The hot press machine locates an adhering prepreg material 13A on a back surface 2C of the base 2 in which the pre-hole 3 is formed, and also locates a copper foil 14 on the adhering prepreg material 13A, and performs hot press. As a result, the hot press machine forms an insulating layer 6A on the back surface 2C of the base 2, and laminates the copper foil 14 on the insulating layer 6A. As a result, the insulating layer 6A constitutes a bottom 8 which closes the opening of the pre-hole 3 on the bottom side.

Further, in the manufacturing method of FIG. 10D, a filling step of filling a melted insulating material 4 into the pre-hole 3 of the base 2 is executed by using a filling machine (not illustrated). At that time, the insulating layer 6A constitutes the bottom 8 of the pre-hole 3, and thus can prevent the filled insulating material 4 from hanging down to the bottom side. A heater thermally cures the insulating material 4 filled in the pre-hole 3, to form a hole-plugging portion 4C in the pre-hole 3. Moreover, a grinding machine (not illustrated) grinds and planarizes the surface portion 2A of the base 2 and the surface of the hole-plugging portion 4C projecting on the base 2. As a result, subsequent steps such as a copper foil laminating step and a pattern forming step can smoothly be performed.

In the manufacturing method of FIG. 10E, a copper foil laminating step of laminating a copper foil 14 on a front surface 2B of the base 2 is executed by using a hot press machine(not illustrated). The hot press machine locates the adhering prepreg material 13 on the surface portion 2A of the base 2, also locates the copper foil 14 on the adhering prepreg material 13, and performs hot press. The hot press machine forms the insulating layer 6 on the surface portion 2A of the base 2, and laminates the copper foil 14 on the insulating layer 6. Further, in the manufacturing method of FIG. 11A, a through hole forming step is executed by using a boring machine (not illustrated). The boring machine forms a plurality of through-hole holes 5A in the hole-plugging portion 4C of the insulating material 4 filled in the pre-hole 3 of the base 2. As a result, insulation of each through-hole hole 5A from each other as well as insulation of each through-hole hole 5A from the base 2 are ensured by the hole-plugging portion 4C of the insulating material 4. Moreover, in the manufacturing method of FIG. 11B, a copper plating is provided to the inner circumferential wall surface of each through-hole hole 5A by using a plating apparatus (not illustrated), to form through holes 5. Then, a patterning apparatus (not illustrated) executes a pattern forming step of forming wiring layers 7 on the insulating layers 6 and 6A on the surface portions 2A of the base 2 as illustrated in FIG. 11C. As a result, the printed wiring board 1D of Embodiment 3 is completed.

In the manufacturing method of Embodiment 3, the insulating layer 6A which is formed on the back surface 2C of the base 2 and on which the copper foil 14 is laminated constitutes the bottom 8 which closes the opening of the pre-hole 3, and the bottom 8 can prevent the insulating material 4 filled in the pre-hole 3 from hanging down. As a result, the workload is reduced in the filling step of filling the insulating material 4 into the pre-hole 3, and hence the workload can be reduced when forming the plurality of through holes 5 in the pre-hole 3 of the base 2 that is a conductive material.

In the printed wiring board 1D of Embodiment 3, the plurality of through holes 5 are formed in the single pre-hole 3. Thus, the surface area of the pre-hole 3 required per through hole 5 in the pre-hole 3 can be suppressed. As a result, the surface area of the hole-plugging portion 4C in the pre-hole 3 decreases, and the amount of the insulating material 4 having a high coefficient of thermal expansion decreases. Thus, this can contribute to decrease in the coefficient of thermal expansion of the entire printed wiring board 1D.

It should be noted that in the manufacturing method of Embodiment 1 described above, the bottom 8 of the pre-hole 3 is formed of the separation film 12 attached to the back surface 2C of the base 2, but may be formed without using another member such as the separation film 12. An embodiment of such a case will be described as Embodiment 4 below.

### Embodiment 4

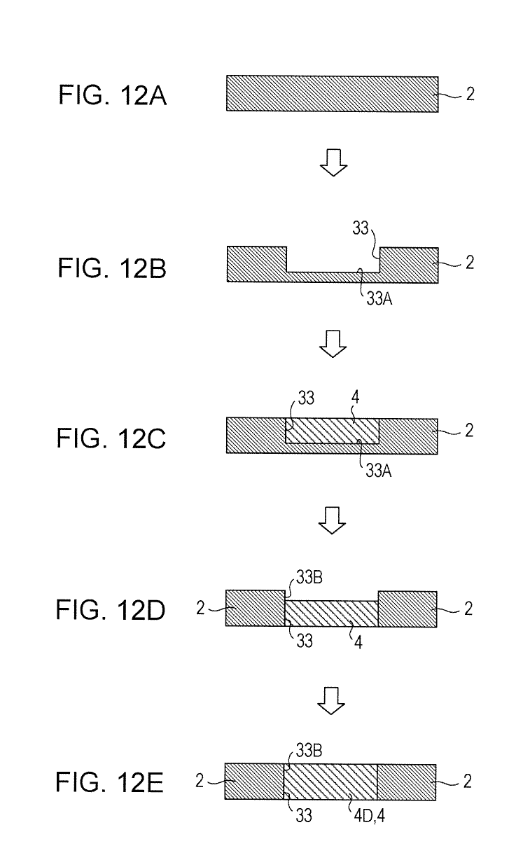

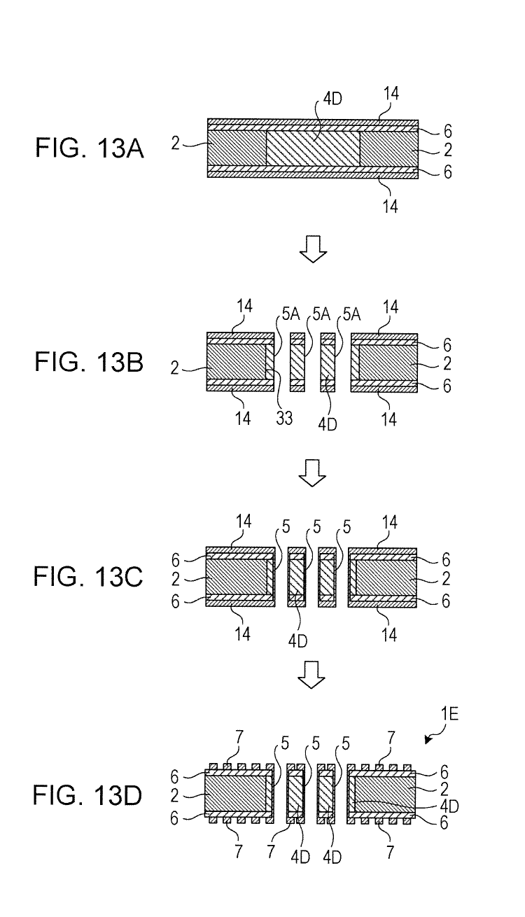

FIGS. 12A to 12E and FIGS. 13A to 13D are diagrams illustrating an example a method for manufacturing of a printed wiring board of Embodiment 4. It should be noted that the same components as those in the printed wiring board 1 of Embodiment 1 described above are designated by the same reference characters, and thus the description of the overlapping configurations and operations is omitted.

In the manufacturing method of FIG. 12A, a base forming step of forming a base 2 is executed by using a hot press machine (not illustrated). The hot press machine stacks a plurality of prepreg materials 11 having low coefficients of thermal expansion, and hot-presses these stacked prepreg materials 11, to form the base 2 having a low coefficient of thermal expansion. Next, in the manufacturing method of FIG. 12B, a pre-hole forming step of forming, in a surface portion 2A of the base 2, a pre-hole 33 having a bottom 33A is executed by using a boring machine (not illustrated).

In the manufacturing method of FIG. 12C, a filling step of filling a melted insulating material 4 into the pre-hole 33 of the base 2 is executed by using a filling machine (not illustrated). At that time, the bottom 33A of the pre-hole 33 can prevent the filled insulating material 4 from hanging down to the bottom side. A heater thermally cures the insulating material 4 filled in the pre-hole 33. In the manufacturing method of FIG. 12D, after the insulating material 4 filled in the pre-hole 33 is thermally cured, the bottom 33A of the pre-hole 33 in which the insulating material 4 is filled is removed by using a boring machine (not illustrated), to form a removal hole 33B which communicates with the pre-hole 33 in which the insulating material 4 is filled.

In the manufacturing method of FIG. 12E, the melted insulating material 4 is filled into the removal hole 33B by using a filling machine (not illustrated). At that time, the previously thermally cured insulating material 4 can prevent the insulating material 4 filled in the removal hole 33B from hanging down. In addition, a heater thermally cures the insulating material 4 filled in the removal hole 33B. As a result, the heater thermally cures the insulating material 4 filled in the removal hole 33B to form a hole-plugging portion 4D. Further, a grinding machine (not illustrated) grinds and planarizes the surface portions 2A of the base 2 and the surface of the hole-plugging portion 4D projecting on the base 2. As a result, subsequent steps such as a copper foil laminating step and a pattern forming step can smoothly be performed.

In the manufacturing method of FIG. 13A, a copper foil laminating step of laminating copper foils 14 on the surface portions 2A of the base 2 is executed by using a hot press machine (not illustrated). The hot press machine locates adhering prepreg materials 13 on the surface portions 2A of the base 2, also locates copper foils 14 on the adhering prepreg materials 13, and performs hot press. The hot press machine forms insulating layers 6 on the surface portions 2A of the base 2, and laminates the copper foils 14 on the insulating layers 6. In addition, in the manufacturing method of FIG. 13B, a through hole forming step is executed by using a boring machine (not illustrated). The boring machine forms a plurality of through-hole holes 5A in the hole-plugging portion 4D of the insulating material 4 filled in the pre-hole 33 of the base 2. As a result, insulation of each through-hole hole 5A from each other as well as insulation of each through-hole hole 5A from the base 2 are ensured by the hole-plugging portion 4D of the insulating material 4. Moreover, in the manufacturing method of FIG. 13C, a copper plating is provided to the inner circumferential wall surface of each through-hole hole 5A by using a plating apparatus (not illustrated), to form through holes 5. Then, in the manufacturing method of FIG. 13D, a pattern forming step of forming wiring layers 7 on the insulating layers 6 on the surface portions 2A of the base 2 is executed by using a patterning apparatus (not illustrated). As a result, the printed wiring board 1E of Embodiment 4 is completed.

In the manufacturing method of Embodiment 4, the pre-hole 33 having the bottom 33A is formed in the base 2, and the insulating material 4 is filled into the pre-hole 33. The bottom 33A can prevent the insulating material 4 filled in the pre-hole 33 from hanging down. In addition, in the manufacturing method, after the insulating material 4 filled in the pre-hole 33 is thermally cured, the bottom 33A of the pre-hole 33 is removed to form the removal hole 33B, and the insulating material 4 is filled into the removal hole 33B. The previously thermally cured insulating material 4 in the pre-hole 33 can prevent the insulating material 4 filled in the removal hole 33B from hanging down. As a result, the workload is reduced in the filling step of filling the insulating material 4 into the pre-hole 3, and hence the workload can be reduced when forming the plurality of through holes 5 in the pre-hole 3 of the base 2 that is the conductive material.

In the printed wiring board 1E of Embodiment 4, the plurality of through holes 5 are formed in the single pre-hole 33. Thus, the surface area of the pre-hole 33 required per through hole 5 in the pre-hole 33 can be suppressed. As a result, the surface area of the hole-plugging portion 4D in the pre-hole 33 decreases, and the amount of the insulating material 4 having a high coefficient of thermal expansion decreases. Thus, this can contribute to decrease in the coefficient of thermal expansion of the entire printed wiring board 1E.

It should be noted in the manufacturing method of Embodiment 2 described above, the surface portions of the first base 20A and the second base 20B are adhered to each other through the insulating layer 30A, but instead of the insulating layer 30A, a multilayer printed wiring board may constitute the bottoms 8 which close the openings of the first pre-hole 3A and the second pre-hole 3B. An embodiment of such a case will be described as Embodiment 5 below.

### Embodiment 5

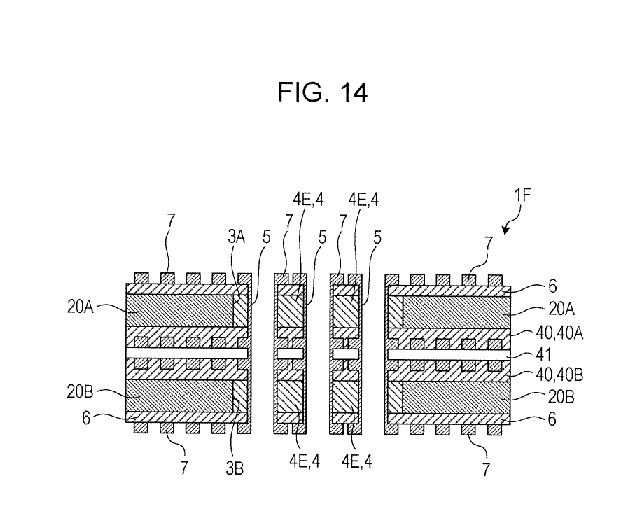

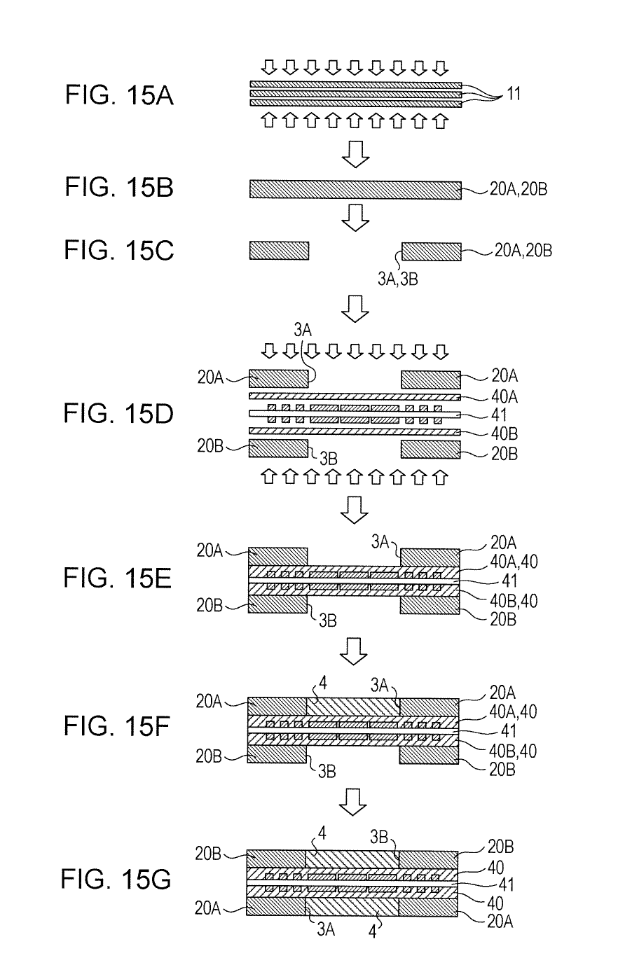

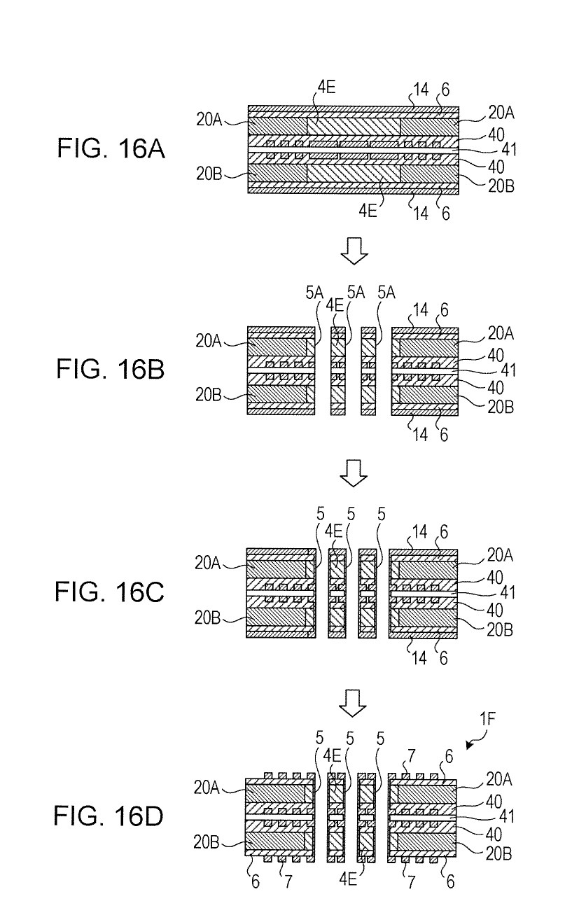

FIG. 14 is a cross-sectional view illustrating an example of a printed wiring board 1F of Embodiment 5. FIGS. 15A to 15G and FIGS. 16A to 16D are diagrams illustrating an example of a method for manufacturing the printed wiring board 1F of Embodiment 5. It should be noted that the same components as those in the printed wiring board 1 of Embodiment 2 described above are designated by the same reference characters, and thus the description of the overlapping configurations and operations is omitted.

The printed wiring board 1F illustrated in FIG. 14 includes a first base 20A, a second base 20B, a first pre-hole 3A, a second pre-hole 3B, and a double-sided wiring layer 41 laminated between the surface portion of the first base 20A and the surface portion of the second base 20B through insulating adhesive layers 40.

Further, the printed wiring board 1F includes hole-plugging portions 4E that are formed by filling an insulating material 4 into the first pre-hole 3A and the second pre-hole 3B and thermally curing the insulating material 4 and plug the first pre-hole 3A and the second pre-hole 3B. In addition, the printed wiring board 1F includes a plurality of through holes 5 that are formed in the hole-plugging portions 4E so as to extend through the first pre-hole 3A, the double-sided wiring layer 41, and the second pre-hole 3B. Moreover, the printed wiring board 1F includes insulating layers 6 formed on the surface portions of the first base 20A and the second base 20B, and wiring layers 7 formed by etching copper foils laminated on the insulating layers 6.

The double-sided wiring layer 41 is, for example, a wiring board in which wirings are provided on both surfaces thereof. The adhesive layers 40 are formed of an adhesive prepreg material 40A located on the front surface of the double-sided wiring layer 41 and an adhesive prepreg material 40B located on the back surface of the double-sided wiring layer 41. The double-sided wiring layer 41 sandwiched between the adhesive prepreg materials 40A and 40B is hot-pressed to form the adhesive layer 40 between the surface portions of the first base 20A and the second base 20B. Then, the adhesive layer 40 joins the surface portions of the first base 20A and the second base 20B to each other. It should be noted that the adhesive layer 40 joins the surface portions of the first base 20A and the second base 20B to each other such that the first pre-hole 3A and the second pre-hole 3B overlap each other. The hole-plugging portions 4E are formed by thermally curing the insulating material 4 filled in the first pre-hole 3A and the second pre-hole 3B, and plug the first pre-hole 3A and the second pre-hole 3B. In the hole-plugging portions 4E, the plurality of through holes 5 are formed so as to conduct the wiring layer 7 on the first base 20A to the wiring layer 7 on the second base 20B.

Next, a method for manufacturing the printed wiring board 1F of Embodiment 5 will be described. FIGS. 15A to 15G and FIGS. 16A to 16D are diagrams illustrating an example of the method for manufacturing the printed wiring board 1F of Embodiment 5. In the manufacturing method of FIG. 15A, by using a hot press machine (not illustrated), a plurality of prepreg materials 11 are stacked, and these stacked prepreg materials 11 are hot-pressed, to form the first base 20A and second base 20B having low coefficients of thermal expansion, as illustrated in FIG. 15B. Next, in the manufacturing method of FIG. 15C, a pre-hole forming step is executed by using a boring machine (not illustrated). The boring machine forms, in the surface portion of the first base 20A, the first pre-hole 3A extending through the front and back thereof, and forms, in the surface portion of the second base 20B, the second pre-hole 3B extending through the front and back thereof.

In the manufacturing method of FIG. 15D, a joining step of joining the surface portions of the first base 20A and the second base 20B to each other is executed by using a hot press machine (not illustrated). The hot press machine locates the double-sided wiring layer 41 sandwiched between the adhesive prepreg materials 40A and 40B at both surfaces thereof, between the first base 20A and the second base 20B such that the first pre-hole 3A and the second pre-hole 3B overlap each other. In other words, the hot press machine locates the adhesive prepreg material 40A between the surface portion of the first base 20A and the front surface of the double-sided wiring layer 41 and locates the adhesive prepreg material 40B between the surface portion of the second base 20B and the back surface of the double-sided wiring layer 41. The hot press machine forms the adhesive layer 40 between the surface portion of the first base 20A and the double-sided wiring layer 41 and forms the adhesive layer 40 between the surface portion of the second base 20B and the double-sided wiring layer 41. As a result, as illustrated in FIG. 15E, the adhesive layers 40 adhere between the surface portion of the first base 20A and the double-sided wiring layer 41 and between the surface portion of the second base 20B and the double-sided wiring layer 41, and constitutes bottoms 8 which close the openings of the first pre-hole 3A and the second pre-hole 3B.

In the manufacturing method of FIG. 15F, a filling step is executed by using a filling machine (not illustrated). The filling machine, for example, causes the opening side of the first pre-hole 3A of the first base 20A to face upward, and fills the melted insulating material 4 into the first pre-hole 3A of the first base 20A. At that time, the adhesive layer 40 constitutes the bottom 8 of the first pre-hole 3A, and thus can prevent the insulating material 4 filled in the first pre-hole 3A from hanging down. A heater thermally cures the insulating material 4 filled in the first pre-hole 3A. It should be noted that after thermally curing the insulating material 4 filled in the first pre-hole 3A, the filling machine causes the opening side of the second pre-hole 3B to face upward. In addition, the filling machine fills the melted insulating material 4 into the second pre-hole 3B of the second base 20B as illustrated in FIG. 15G. At that time, the adhesive layer 40 constitutes the bottom 8 of the second pre-hole 3B, and thus can prevent the insulating material 4 filled in the second pre-hole 3B from hanging down. Further, the heater thermally curs the insulating material 4 filled in the second pre-hole 3B. As a result, the heater causes the thermally cured insulating material 4 to form the hole-plugging portions 4E in the first pre-hole 3A and the second pre-hole 3B. Further, a grinding machine (not illustrated) grinds and planarizes the surface portions 2A of the base 2 and the surface of the hole-plugging portions 4E projecting on the base 2. As a result, subsequent steps such as a copper foil laminating step and a pattern forming step can smoothly be performed.

In the manufacturing method of FIG. 16A, a copper foil laminating step of laminating copper foils 14 on the surface portions of the first base 20A and the second base 20B is executed by using a hot press machine (not illustrated). The hot press machine locates adhering prepreg materials 13 on the surface portions of the base 2, also locates the copper foils 14 on the adhering prepreg materials 13, and performs hot press. The hot press machine forms the insulating layers 6 on the surface portions of the first base 20A and the second base 20B and laminates the copper foils 14 on the insulating layers 6. In addition, in the manufacturing method of FIG. 16B, a plurality of through-hole holes 5A are formed in the hole-plugging portions 4E of the insulating material 4 filled in the first pre-hole 3A and the second pre-hole 3B, by using a boring machine (not illustrated). As a result, insulation of each through-hole hole 5A from each other as well as insulation of each through-hole hole 5A from the first base 20A and the second base 20B are ensured by the hole-plugging portions 4E of the insulating material 4.

Further, in the manufacturing method of FIG. 16C, a copper plating is provided to the inner circumferential wall surface of each through-hole hole 5A by using a plating apparatus (not illustrated), to form the through holes 5. Then, in the manufacturing method of FIG. 16D, a pattern forming step of forming the wiring layers 7 on the insulating layers 6 on the surface portions of the first base 20A and the second base 20B is executed by using a patterning apparatus (not illustrated). As a result, the printed wiring board 1F of Embodiment 5 is completed.

In the manufacturing method of Embodiment 5, the surface portions of the first base 20A and the second base 20B are joined to each other through the adhesive layers 40 sandwiching the double-sided wiring layer 41, and each adhesive layer 40 constitutes the bottom 8 which closes the opening of the first pre-hole 3A or the second pre-hole 3B. Further, in the manufacturing method, the bottoms 8 can prevent the insulating material 4 filled in the first pre-hole 3A and the second pre-hole 3B from hanging down. As a result, the workload is reduced in the filling step of filling the insulating material 4 into the first pre-hole 3A and the second pre-hole 3B, and hence the workload can be reduced when forming the plurality of through holes 5 in the first pre-hole 3A and the second pre-hole 3B of the conductive first base 20A and second base 20B.

In the printed wiring board 1F of Embodiment 5, the first pre-hole 3A and the second pre-hole 3B constitute the single pre-hole 3, and the plurality of through holes 5 are formed in the pre-hole 3. Therefore, the surface area of the pre-hole 3 required per through hole 5 in the pre-hole 3 can be suppressed as compared to the existing art of an arrangement configuration in which one through hole is formed in on pre-hole. As a result, the surface areas of the hole-plugging portions 4E in the first pre-hole 3A and the second pre-hole 3B decrease, and the amount of the insulating material 4 having a high coefficient of thermal expansion decreases. Thus, this can contribute to decrease in the coefficient of thermal expansion of the entire printed wiring board 1F.

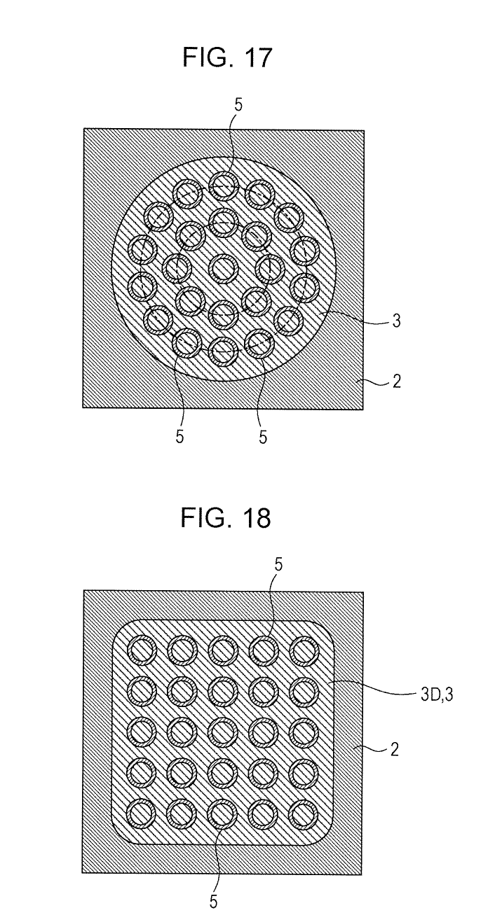

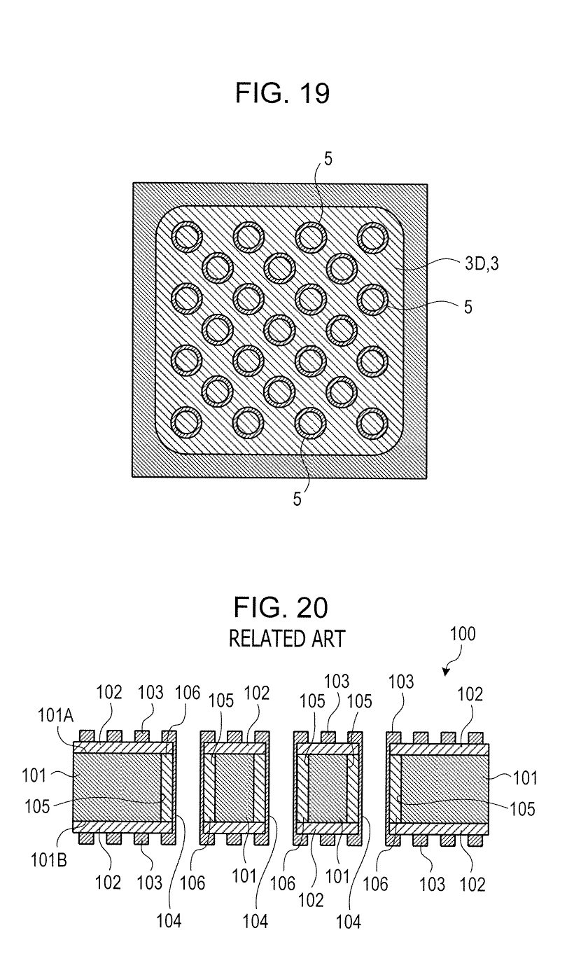

In Embodiments 1 to 5 described above, the arrangement configuration in which the seven through holes 5 are formed in the single pre-hole 3 is provided as illustrated in FIG. 4, but an arrangement configuration described below may be provided. FIGS. 17 to 19 are diagrams illustrating examples where a plurality of through holes 5 are formed in a single pre-hole 3. The arrangement configuration of the through holes 5 illustrated in FIG. 17 is an example where 23 through holes 5 are formed in a circular pre-hole 3. The arrangement configuration of the through holes 5 illustrated in FIG. 18 is an example of an arrangement configuration of a normal lattice in which five through holes 5 are formed in each column in a rectangular pre-hole 3D and five through holes are formed in each row in the pre-hole 3D, namely, 25 through holes 5 are formed. The arrangement configuration of the through holes 5 illustrated in FIG. 19 is an example of a houndtooth arrangement configuration in which 25 through holes 5 are formed in a rectangular pre-hole 3D.

In each embodiment described above, the printed wiring board 1 (1A to 1F) has been described as an example. However, the disclosed technology may be applied to a probe card which tests a printed wiring board.

Further, in each embodiment described above, the values of the coefficient of thermal expansion, the elastic moduli, the dimensions, and the like of the materials used for manufacturing the printed wiring board have specifically been specified. However, these specified values are merely an example of the invention of the present application, and the technical idea of the invention of the present application is not unduly limited by these values.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A method of manufacturing a printed wiring board, the method comprising:
forming a first hole penetrating a base having conductivity;
closing an opening of the first hole with a film;
filling an insulating material into the first hole after closing the opening;
removing the film after filling the insulating material;
forming a plurality of second holes penetrating the insulating material; and
forming a film having conductivity on an inner surface of each of the second holes to form a plurality of wirings penetrating the insulating material.

2. The method of manufacturing the printed wiring board according to claim 1, wherein each of the second holes has a center on a circle concentric with the first hole.

3. The method of manufacturing the printed wiring board according to claim 1, wherein the base includes a conductive material having a low coefficient of thermal expansion.

4. The method of manufacturing the printed wiring board according to claim 3, wherein the base includes at least one of prepreg material including a fabric of carbon fiber and an invar material.

5. A method of manufacturing a printed wiring board, the method comprising:
forming a first hole penetrating a base having conductivity;
closing an opening of the first hole with an insulating layer;
filling an insulating material into the first hole after closing the opening;
forming a plurality of second holes penetrating the insulating material and the insulating layer; and
forming a film having conductivity on an inner surface of each of the second holes to form a plurality of wirings penetrating the insulating material and the insulating layer.

6. The method of manufacturing the printed wiring board according to claim 5, wherein each of the second holes has a center on a circle concentric with the first hole.

7. The method of manufacturing the printed wiring board according to claim 5, wherein the base includes a conductive material having a low coefficient of thermal expansion.

8. The method of manufacturing the printed wiring board according to claim 7, wherein the base includes at least one of prepreg material including a fabric of carbon fiber and an invar material.

9. A method of manufacturing a printed wiring board, the method comprising:
removing a portion of a base having conductivity to form a hole having a bottom which is a part of the base;
filling an insulating material into the hole;
removing the bottom to expose the first insulating material;
forming a plurality of third holes penetrating the insulating material; and
forming a film having conductivity on an inner surface of each of the third holes to form a plurality of wirings penetrating the insulating material.

10. The method of manufacturing the printed wiring board according to claim 9, wherein each of the third holes has a center on a circle concentric with the hole.

11. The method of manufacturing the printed wiring board according to claim 9, wherein the base includes a conductive material having a low coefficient of thermal expansion.

12. The method of manufacturing the printed wiring board according to claim 11, wherein the base includes at least one of prepreg material including a fabric of carbon fiber and an invar material.

13. A method of manufacturing a printed wiring board, the method comprising:
forming a first hole penetrating a first base having conductivity;
forming a second hole penetrating a second base having conductivity;
laminating the first base and the second base such that the first hole and the second hole correspond to each other and an insulating layer is interposed between the first base and the second base;
filling a first insulating material and a second insulating material into the first hole and the second hole, respectively, after laminating the first base and the second base;
forming a plurality of third holes penetrating the first insulating material, the second insulating material and the insulating layer; and
forming a film having conductivity on an inner surface of each of the third holes to form a plurality of wirings penetrating the first insulating material, the second insulating material and the insulating layer.

14. The method of manufacturing the printed wiring board according to claim 13, wherein
the filling a first insulating material and a second insulating material includes:
filling the first insulating material into the first hole;
curing the first insulating material after filling the first insulating material;
filling the second insulating material into the second hole after curing the first insulating material; and
further curing the first insulating material and the second insulating material after filling the second insulating material.

15. The method of manufacturing the printed wiring board according to claim 13, wherein
the filling a first insulating material and a second insulating material includes:
filling the first insulating material into the first hole;
curing the first insulating material after filling the first insulating material;
filling the second insulating material into the second hole after curing the first insulating material; and
curing the second insulating material after filling the second insulating material.

16. The method of manufacturing the printed wiring board according to claim 13, wherein each of the third holes has a center on a circle concentric with the first hole or the second hole.

17. The method of manufacturing the printed wiring board according to claim 13, wherein each of the first base and the second base includes a conductive material having a low coefficient of thermal expansion.

18. The method of manufacturing the printed wiring board according to claim 17, wherein each of the first base and the second base includes at least one of prepreg material including a fabric of carbon fiber and an invar material.

19. A printed wiring board comprising:
a first base having conductivity;
a first insulating material penetrating the first base;
a second base having conductivity;
a second insulating material penetrating the second base;
insulating layer provided between the first base and the second base and between the first insulating material and the second insulating material; and
a plurality of wirings penetrating the first insulating material, the second insulating material and the insulating layer.
